(19) United States
(12) Patent Application Publication
(10) Pub. No.: US 2022/0085304 A1
(43) Pub. Date: Mar. 17, 2022

(54) ALKYNYL AU (III) COMPLEX AND LIGHT-EMITTING DEVICE

(71) Applicant: SICHUAN KNOWLEDGE EXPRESS INSTITUTE FOR INNOVATIVE TECHNOLOGIES CO., LTD., Tianfuxinqu Meishan, Sichuan (CN)

(72) Inventors: Chi Ming CHE, Hong Kong (CN); Wai Pong TO, Hong Kong (CN); So Ming TONG, Hong Kong (CN); Dongling ZHOU, Hong Kong (CN)

(73) Assignee: SICHUAN KNOWLEDGE EXPRESS INSTITUTE FOR INNOVATIVE TECHNOLOGIES CO., LTD., Tianfuxinqu Meishan, Sichuan (CN)

(21) Appl. No.: 17/415,722

(22) PCT Filed: Dec. 19, 2019
(86) PCT No.: PCT/CN2019/126665

§ 371 Date: Jun. 18, 2021

(30) Foreign Application Priority Data
Dec. 21, 2018 (CN) 201811569709.8

(51) Int. Cl. H01L 51/00; C09K 11/06; C07F 1/00

(52) U.S. Cl. CPC H01L 51/0091; C09K 11/06; C07F 1/00; H01L 51/5016; C09K 2211/1029; C09K 2211/1007; C09K 2211/188

(57) ABSTRACT

The invention provides an alkynyl Au (III) complex having the structure shown in Formula I, wherein R¹-R¹⁷ are as defined in the specification. The alkynyl Au (III) complex provided by the invention has excellent luminescent properties such as short luminescence life, high external quantum efficiency, and efficiency roll reduced in actual high-luminance use, and is currently the best result obtained in the research of Au (III) complexes, especially alkynyl Au (III) complexes. In addition the invention further provides a light-emitting device.

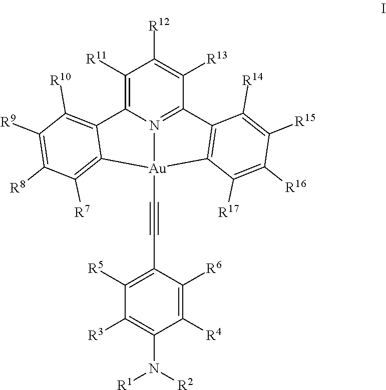

### CROSS REFERENCE TO RELATED APPLICATIONS

This application claims priority of Chinese patent application CN 201811569709.8 filed on Dec. 21,2018, the disclosures of which are hereby incorporated by reference.

### TECHNICAL FIELD OF THE INVENTION

The invention belongs to the technical field of coordination chemistry and light-emitting materials, and specifically relates to an Au (III) complex and a light-emitting device.

### DESCRIPTION OF THE PRIOR ART

Organic electroluminescent diode (OLED) serves as a new generation of display and lighting technology, with the key to its performance that light-emitting materials are used. At present, people mainly concentrate light-emitting materials on studying Pt(II), Ir(III) or Ru(II) complexes, and some of which have been commercialized as light-emitting materials and used in flat panel displays of electronic products. As people require expanding display or lighting technology in more fields and pursue high performance and low cost, it is of great significance to develop light-emitting materials based on a wider range of metal complexes, especially based on cheaper metal complexes.

The light-emitting materials emit light mainly based on phosphorescence and fluorescence. In the metal complex, the part of the electrons that are excited from the ground state (S0) and then jump to the singlet excited state (S1 state), return to the ground state by radiation with emitting fluorescence, and normally have theoretical quantum efficiency of only about 25%, while the remaining part (about 75%) reach the triplet excited state (T1 state) through intersystem crossing, and then accelerate the intersystem crossing under the action of central heavy metal atoms, which enables the electrons to return to the S0 ground state from the T1 state by radiation with emitting phosphorescence at normal temperature. Due to the spin-forbidden transition from T1 to S0, the T1 state has a relatively low radiation attenuation rate, so the luminescence lifetime is longer. In this process, the electrons in the T1 state may partly return to the S1 state through reverse intersystem crossing (RISC), or they may be consumed by self-quenching such as internal collisions. Therefore, the longer the luminescence lifetime, the more electrons returns through the reverse intersystem crossing and are consumed by the self-quenching, and the lower the quantum efficiency. Furthermore, the corresponding external quantum efficiency (EQE) of a device will also show some varying degrees of decrease with increase of luminance, that is, the efficiency roll-off occurs, and the excessive efficiency roll-off is inconducive to the commercial application of light-emitting materials. For example, the applicable luminance of a display device is 100-1000 cd/m², while the applicable luminance of lighting is 1000-5000 cd/m². It can be seen that photoluminescence quantum efficiency and luminescence lifetime are important indicators for evaluating the performance of light-emitting materials.

In the past two years, there are some breakthroughs in thermally activated delayed fluorescence (TADF) materials for the application of OLEDs. When these materials are thermally activated, about 75% of the excitons in the T1 state reach the S1 state through the RISC channel, and emit long-life fluorescence. Therefore, in the light-emitting material, the electrons that are excited to jump to the S1 state, and the electrons that return to the S1 state through reverse intersystem crossing, can all emit fluorescence by returning to the S0 state with radiation. That theoretical internal quantum efficiency reaches 100%, and superposition of ordinary fluorescence and delayed fluorescence can greatly improve the luminous efficiency of the metal complex. However, as the energy level of the T1 state is often lower than that of the S1 state, the incidence of reverse intersystem crossing from the T1 state is often low, but when the energy gap between the S1 state and the T1 state (AEST)) is narrow enough (<800 cm⁻¹), and when the T1 state has a low radiation attenuation rate, the ratio of RISC at room temperature can be greatly increased[Chem. Soc. Rev. 2017, 46, 915].

In the existing literature, since it was reported that Au (III) complexes had been used as light-emitting materials, they have attracted more attention. Among them, The result obtained from alkynyl Au (III) multidentate complex is better. The maximum external quantum efficiency (EQE value) of the related alkynyl Au (III) complex prepared by the solution method is 15.3%, while the device having alkynyl Au (III) complex prepared by vacuum deposition method has the best EQE of 20.3% under low luminance. However, it is limited by the efficiency roll-off, that is, as the luminance increases, the EQE drops sharply. When the luminance is 1000 candela/square meter (cd/A), the EQE drop (efficiency roll-off) is up to 90%. Due to the low quantum efficiency and severe self-quenching, it is difficult to use high doping concentration, so it will take a long effort to realize commercial applications. Studies have shown that it has photo-phosphorescence of excimers based on charge transfer in triplet ligand or between ligand-ligand and generated through π-π stacking of CANAC ligands. Further studies have shown that the triplet excited state T1 of these alkynyl Au (III) complexes shows a low radiation attenuation rate, about 10²-10³ s⁻¹, due to the spin-forbidden transition from the T1 state to the S0 state, so it is inconducive to obtaining higher quantum efficiency. That causes the existing alkynyl Au (III) complex to meet the requirements of light-emitting materials difficultly for high-luminance display of commercialized OLEDs, and the slow light-emitting mechanism of a light-emitting substance is the main shortcomings and limitation that it is difficultly used as a light-emitting substance in OLEDs. Therefore, that needs a long way to go for developing new OLED light-emitting materials using Au (III) complexes as cheap alternatives.

In addition, the structure of a typical OLED light-emitting device is a sandwich-like intercalated structure with multiple organic semiconductor layers arranged between the positive and negative electrodes, which mainly includes: hole injection layer, hole transport layer, light emitting layer, electron transport layer, electron injection layer. Among them, the filling composition and process parameters of the OLED light-emitting device often have an important impact on the light-emitting performance Therefore, it is of great significance to explore and develop a light-emitting device that can fully present and improve the light-emitting performance of light-emitting materials for different types of light-emitting materials.

### SUMMARY OF THE INVENTION

For the shortcomings of the prior art, the purpose of the present invention is to develop a new alkynyl Au (III) complex with the structure shown in Formula I, which presents the characteristics of thermally activated delayed fluorescence (TADF) at room temperature. The complex can be used as light-emitting materials or dopants in organic electroluminescent diodes (OLEDs) to achieve higher external quantum efficiency and shorter luminescence lifetime, as well as there is no obvious efficiency roll-off within 1000 cd/A of luminance, which has a larger commercialization prospect.

### Definition

In order to facilitate the understanding of the subject matter disclosed herein, terms, abbreviations or other shorthand are defined below. Any term, abbreviation or shorthand not defined is understood to have the ordinary meaning used by a person skilled in the art contemporaneous with the submission of this application.

“Halogen” refers to fluorine, chlorine, bromine and iodine.

“Amino” refers to a primary, secondary, or tertiary amine which may be optionally substituted. Specifically included are secondary or tertiary amine nitrogen atoms which are members of a heterocyclic ring. Also specifically included, for example, are secondary or tertiary amino groups substituted by an acyl moiety. Some non-limiting examples of an amino group include —NR′R″ wherein each of R′ and R″ is independently H, alkyl, aryl, aralkyl, alkaryl, cycloalkyl, acyl, heteroalkyl, heteroaryl or heterocycyl.

“Alkyl” refers to a fully saturated acyclic monovalent group having carbon and hydrogen, and which may be branched or a straight chain, and which may have 1-20 carbon atoms, for example, 1-15 carbon atoms, 1-10 carbon atoms, 1-8 carbon atoms, or 1-6 carbon atoms. Examples of alkyl groups include, but are not limited to, methyl, ethyl, n-propyl, isopropyl, n-butyl, t-butyl, n-heptyl, n-hexyl, n-octyl, and n-decyl.

“Alkoxy” refers to the radical—OR obtained by replacing the hydrogen in a hydroxyl group with an alkyl group, where R is an alkyl group as defined above. Exemplary alkoxy groups include, but are not limited to, methoxy, ethoxy, n-propoxy, and isopropoxy.

“Cycloalkyl” refers to a monocyclic alkyl group, a fused or non-fused polycyclic alkyl group, and may have 4-20 carbon atoms, for example, 5-20 carbon atoms, 5-12 carbon atoms, 5-8 carbon atoms or 3-6 carbon atoms, including but not limited to cyclopropyl, cyclobutyl, cyclopentyl or cyclohexyl.

“Heterocyclic alkyl” refers to a monocyclic alkyl group, a fused or non-fused polycyclic alkyl group having one or more heteroatoms (O, N, S, P, Si, etc.), and may have 3-20 carbon atoms, for example, 3-20 carbon atoms and 1-4 heteroatoms, 4-12 carbon atoms and 1-4 heteroatoms, 4-8 carbon atoms and 1-3 heteroatoms, or 2-6 carbon atoms and 1-2 heteroatoms, or 3-6 carbon atoms and 1 heteroatom. Examples of heterocyclic alkyl include, but are not limited to, pyrrolidinyl, tetrahydrofuranyl, tetrahydrothienyl, tetrahydrothiazolyl, t etrahydroxazolyl, piperidinyl, piperazinyl, thiazinyl or 1-3 oxacyclohexane.

“Aromatic” or “aromatic group” refers to aryl or heteroaryl.

“Aryl” refers to an optionally substituted carbocyclic aromatic group, which may be a monocyclic or fused or non-fused polycyclic aryl group, and which may have 6-20 carbon atoms, for example, 6-16 carbon atoms, 6-12 carbon atoms, or 6-10 carbon atoms, some non-limiting examples of aryl groups include phenyl, biphenyl, naphthyl, substituted phenyl, substituted biphenyl, or substituted naphthalene. In other examples, the aryl group is phenyl or substituted phenyl.

“Aryloxy” refers to the radical—OAr obtained by replacing the hydrogen in a hydroxyl group with an aryl group, where Ar is an aryl group as defined above. Exemplary aryloxy groups include, but are not limited to, phenoxy, biphenoxy, naphthoxy, and substituted phenoxy.

“Heteroaryl” refers to a monocyclic aryl group, a fused or non-fused polycyclic aryl group having more than one heteroatom (O, N, S, P, Si, etc.), and may have 3-20 carbon atoms, for example, 3-20 carbon atoms and 1-4 heteroatoms, 3-12 carbon atoms and 1-4 heteroatoms, 3-8 carbon atoms and 1-3 heteroatoms, 2-5 carbon atoms and 1-2 heteroatoms, or 4-5 carbon atoms and 1 heteroatom. Some non-limiting examples of heteroaryl groups include thiazolyl, oxazolyl, imidazolyl, isoxazolyl, pyrrolyl, pyrazolyl, thienyl, furyl, pyridyl, pyrimidinyl, pyrazinyl, pyridazine Group, indolyl, quinolinyl, isoquinolinyl, quinoxalinyl, bipyridyl, acridinyl, phenanthridinyl, phenanthroline, quinazolone, benzimidazolyl, benzothiophene, benzothiazolyl, benzoxazolyl, benzisoxazolyl.

Where, “heteroalkyl”, “heterocycloalkyl” or “heteroaryl” contains one or more heteroatoms, preferably 1-6 heteroatoms, more preferably 1-3 heteroatoms, which include, but not limited to one or more selected from oxygen, nitrogen or sulfur atoms. When there are multiple heteroatoms, the multiple heteroatoms are the same or different.

“Substituted” as used herein to describe a compound or chemical moiety refers to that at least one hydrogen atom of that compound or chemical moiety is replaced with a second chemical moiety. Non-limiting examples of substituents are those found in the exemplary compounds and examples disclosed herein. And, when the “alkyl” or “alkoxy” is substituted, those also includes unsaturated carbon-carbon bonds or are substituted by one or more of the following substituents: fluorine, chlorine, bromine, iodine, hydroxyl, oxygen, amino, primary amino, secondary amino, imino, nitro, nitroso, cyano, substituted or unsubstituted C₁-C₈ alkoxy, substituted or unsubstituted C₃-C₈ cycloalkyl, substituted or unsubstituted C₂-C₇ heterocyclic alkyl, substituted or unsubstituted C₆-C₁₀ aryl, or substituted or unsubstituted C₄-C₉ heteroaryl. Where, when the substituent is oxygen, those refer to a carbonyl group formed by oxygen with the carbon connected to it, for example, ketone carbonyl group, an aldehyde group, an ester group, an alkyl acyl group, an aryl acyl group, an amide group and the like. When the “aryl”, “aryloxy” or “heteroaryl” is substituted, those also are substituted by one or more of the following substituents: fluorine, chlorine, bromine, iodine, hydroxyl, amino, primary amino, secondary amino, imino, nitro, nitroso, cyano, substituted or unsubstituted C₁-C₈ alkyl, substituted or unsubstituted C₁-C₈ alkoxy, substituted or unsubstituted C₃-C₈ cycloalkyl, substituted or unsubstituted C₂-C₇ heterocyclic alkyl, or substituted or unsubstituted C₄-C₉ heteroaryl. In the invention, preferably, one, two, three, four, five, or six substituents or perhalogen are preferred for substitutions, for example, trifluoromethyl, perfluorophenyl, and when the substituent contains hydrogen, the above-mentioned substituents may be optionally further substituted by substituents selected from such groups.

In addition, the substituent may include a moiety in which a carbon atom is replaced by a heteroatom such as nitrogen, oxygen, silicon, phosphorus, boron, sulfur, or halogen. These substituents may include halogen, heterocycle, alkoxy, alkenyloxy, alkynyloxy, aryloxy, hydroxyl, protected hydroxyl, keto, acyl, acyloxy, nitro, amino, amido, cyano, mercaptans, ketals, acetals, esters and ethers.

Some non-limiting examples of electron-withdrawing substituents include: F, Cl, trifluoromethyl, nitro, nitroso, cyano, isocyano, carboxyl, sulfonic acid, perfluorophenyl, 2,4,6-trifluorophenyl, 3,4,5-trifluorophenyl, 2,4,6-tritrifluoromethylphenyl, 2,4,6-trinitrophenyl, trifluoromethylethynyl, perfluorovinyl, trifluoromethanesulfonyl, p-trifluoromethylbenzenesulfonyl.

In order to achieve the purpose of the invention, the invention provides an alkynyl Au (III) complex, which has the structure shown in the following Formula I on the one hand.

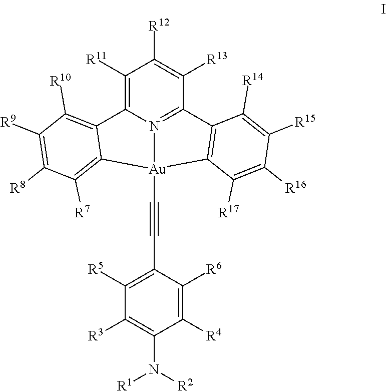

Where, R¹ and R² are independently a hydrogen atom, a deuterium atom, a substituted or unsubstituted alkyl group, a substituted or unsubstituted cycloalkyl group, a substituted or unsubstituted heterocycloalkyl group, a substituted or unsubstituted aryl group, a substituted or unsubstituted heteroaryl group, and R¹ and R² can also form a nitrogen-having heterocyclic 5-membered ring or a nitrogen-having heterocyclic 6-membered ring with a N atom connected to them, which refers to that the direct bonding between the aromatic rings of R¹ and R² forms a 6-5-6 fused ring structure with a N atom connected to them or that the bonding of the substituents on that aromatic ring (for example, bonded by 0, S, C, N, P and other atoms) forms a 6-6-6 fused ring structure with a N atom connected to them.

R³-R⁶ and R⁷—R′⁷ are independently a hydrogen atom, a deuterium atom, a halogen atom, a trifluoromethyl group, a nitro group, a nitroso group, a cyano group, an isocyano group, a carboxyl group, a sulfonic acid group, a hydroxyl group, a sulfhydryl group, a substituted or unsubstituted alkoxy group, a substituted or unsubstituted aryloxy group, a substituted or unsubstituted alkylsulfonyl group, a substituted or unsubstituted arylsulfonyl group, a substituted or unsubstituted amino group, a substituted or unsubstituted alkyl group, a substituted or unsubstituted cycloalkyl group, a substituted or unsubstituted heterocycloalkyl group, a substituted or unsubstituted aryl group, a substituted or unsubstituted heteroaryl group, and two adjacent groups in R⁷-R¹⁷ can also partially or completely form a 5-8 membered ring with 2 or 4 carbon atoms in the connected parent ring;

at least two groups in R⁷-R¹⁷ are electron-withdrawing substituents, and said electron-withdrawing substituents are independently a F atom, a Cl atom, a trifluoromethyl group, a nitro group, a nitroso group, a cyano group, an isocyano group, a carboxyl group or a sulfonic acid group, or are an aryl group, an heteroaryl group, a 1-unsaturated alkyl group, a 1-oxoalkyl group, an alkylsulfonyl group or an arylsulfonyl group that are substituted by at least one of F, Cl, a trifluoromethyl group, a nitro group, a nitroso group, a cyano group, an isocyano group, a carboxyl group or a sulfonic acid group.

In one example, R¹ and R² are independently a hydrogen atom, a deuterium atom, a substituted or unsubstituted alkyl group having 1-20 carbon atoms, a substituted or unsubstituted cycloalkyl group having 4-20 carbon atoms, a substituted or unsubstituted heterocycloalkyl group having 4-20 carbon atoms, a substituted or unsubstituted aryl group having 6-20 carbon atoms, or a substituted or unsubstituted heteroaryl group having 4-20 carbon atoms.

In one example, R¹ and R² are independently a substituted or unsubstituted aryl group having 6-20 carbon atoms. In one example, R¹ and R² are independently a substituted or unsubstituted aryl group having 6-16 carbon atoms. In one example, R¹ and R² are independently a substituted or unsubstituted aryl group having 6-12 carbon atoms. In one example, R¹ and R² are independently a substituted or unsubstituted aryl group having 6-10 carbon atoms. In one example, R¹ and R² are independently a substituted or unsubstituted phenyl group.

In one example, R³-R¹⁷ are independently a hydrogen atom, a deuterium atom, a halogen atom (such as F, Cl, Br and I atom), a trifluoromethyl group, a nitro group, a nitroso group, a cyano group, an isocyano group, a carboxyl group, a sulfonic acid group, a hydroxyl group, a sulfhydryl group, a substituted or unsubstituted alkoxy group having 1-20 carbon atoms, a substituted or unsubstituted aryloxy group having 6-20 carbon atoms, a substituted or unsubstituted alkylsulfonyl group having 1-20 carbon atoms, a substituted or unsubstituted arylsulfonyl group having 6-20 carbon atoms, a substituted or unsubstituted amino group having 0-20 carbon atoms, a substituted or unsubstituted alkyl group having 1-20 carbon atoms, a substituted or unsubstituted cycloalkyl group having 5-20 carbon atoms, a substituted or unsubstituted heterocycloalkyl group having 3-20 carbon atoms, a substituted or unsubstituted aryl group having 6-20 carbon atoms, or a substituted or unsubstituted heteroaryl group having 3-20 carbon atoms.

In one example, optionally at least two groups in R⁷-R¹⁰ and R¹⁴-R¹⁷ are independently a F atom, a Cl atom, a trifluoromethyl group, a nitro group, a nitroso group, a cyano group, an isocyano group, a carboxyl group, a sulfonic acid group, a substituted or unsubstituted aryl group having 6-12 carbon atoms, a substituted or unsubstituted heteroaryl group having 4-12 carbon atoms, a substituted or unsubstituted 1-unsaturated alkyl group having 2-10 carbon atoms, a substituted or unsubstituted 1-oxoalkyl group having 1-10 carbon atoms, a substituted or unsubstituted alkylsulfonyl group having 1-10 carbon atoms, or a substituted or unsubstituted arylsulfonyl group having 6-12 carbon atoms, where among said substituted or unsubstituted aryl group having 6-12 carbon atoms, said substituted or unsubstituted 1-unsaturated alkyl group having 2-10 carbon atoms, said substituted or unsubstituted 1-oxoalkyl group having 1-10 carbon atoms, said substituted or unsubstituted alkylsulfonyl group having 1-10 carbon atoms sand said substituted or unsubstituted arylsulfonyl group having 6-12 carbon atoms, the substitution refers to being substituted by at least one of a F atom, a Cl atom, a trifluoromethyl group, a nitro group, a nitroso group, a cyano group, an isocyano group, a carboxyl group and a sulfonic acid group.

In one example, R¹¹-R¹³ are independently a hydrogen atom, a deuterium atom, a halogen atom, a trifluoromethyl group, a nitro group, a nitroso group, a cyano group, an isocyano group, a carboxyl group, a sulfonic acid group, a hydroxyl group, a sulfhydryl group, a substituted or unsubstituted alkoxy group having 1-10 carbon atoms, a substituted or unsubstituted aryloxy group having 6-12 carbon atoms, a substituted or unsubstituted alkylsulfonyl group having 1-10 carbon atoms, a substituted or unsubstituted arylsulfonyl group having 6-12 carbon atoms, a substituted or unsubstituted amino group having 0-12 carbon atoms, a substituted or unsubstituted alkyl group having 1-10 carbon atoms, a substituted or unsubstituted cycloalkyl group having 5-12 carbon atoms, a substituted or unsubstituted heterocycloalkyl group having 3-12 carbon atoms, or a substituted or unsubstituted heteroaryl group having 3-12 carbon atoms.

In one example, R³-R⁶ are independently a hydrogen atom, a deuterium atom, a Br atom, a I atom, a trimethylsilyl atom, a hydroxyl atom, a sulfhydryl atom, a substituted or unsubstituted alkoxy group having 1-10 carbon atoms, a substituted or unsubstituted aryloxy group having 6-12 carbon atoms, a substituted or unsubstituted amino group having 0-10 carbon atoms, a substituted or unsubstituted alkyl group having 1-10 carbon atoms, a substituted or unsubstituted cycloalkyl group having 5-12 carbon atoms, a substituted or unsubstituted heterocycloalkyl group having 3-12 carbon atoms, a substituted or unsubstituted aryl group having 6-12 carbon atoms, or a substituted or unsubstituted heteroaryl group having 3-12 carbon atoms.

In one example, R⁸, R¹⁰, R¹⁴ and R¹⁶ are an electron-withdrawing substituent, which is as described above. R⁷, R⁹, R¹¹-R¹³, R¹⁵ and R¹⁷ are a hydrogen group. R¹ and R² are independently a phenyl group, or R¹ and R² are a phenyl group where the 2-position is directly or indirectly connected with each other. R⁸ and R¹⁰ are same with each other, and R¹⁴ and R¹⁶ are same with each other.

In one example, R⁸, R¹⁰, R¹⁴, and R¹⁶ are independently a halogen atom, such as a fluorine atom.

In one example, R⁷, R⁹, R¹¹-R¹³, R¹⁵ and R¹⁷ are independently a hydrogen atom. In one example, R¹² is a hydrogen atom, an alkyl group or a halogen group.

In one example, R³-R⁶ are independently a hydrogen atom or an alkyl group (for example, a substituted or unsubstituted alkyl group having 1-10 carbon atoms, a substituted or unsubstituted alkyl group having 1-6 carbon atoms).

In another example, the total number of carbon atoms provided by the R³-R¹⁷ group is 0-40, preferably 0-20.

In another example, the total number of carbon atoms provided by the R³-R¹⁷ group is 0-30, preferably 0-15.

In another example, the total number of carbon atoms provided by the R¹ and R² groups is 0-60, preferably 12-30.

Some specific non-limiting examples of the alkynyl Au (III) complexes having the Formula I are as follow:

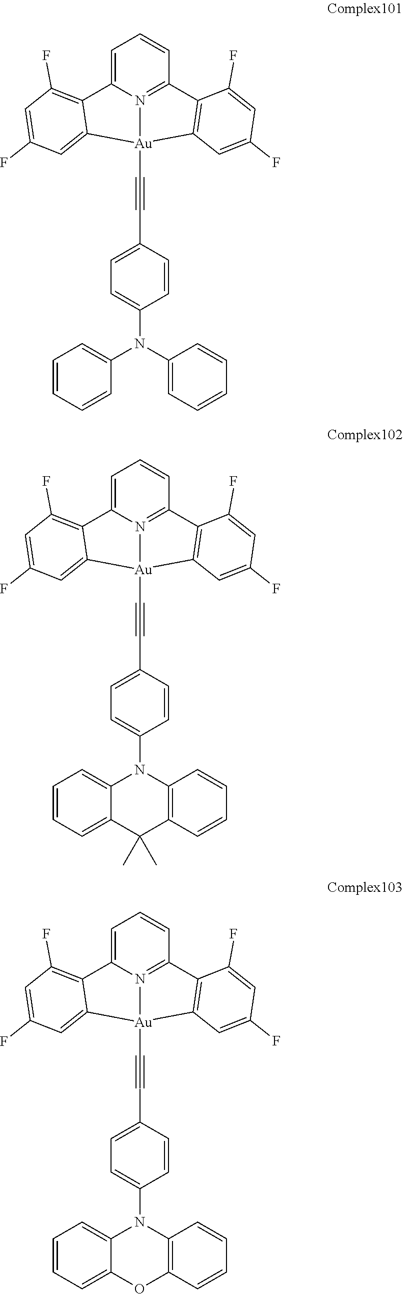

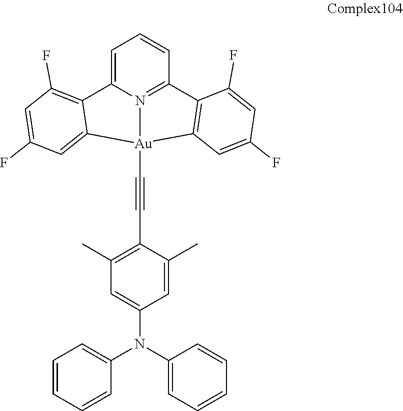

The alkynyl Au (III) complex provided by the invention has performance of photoluminescence and electroluminescence, and can be used to form thin films by sublimation, vacuum deposition, spin coating, inkjet printing or other known preparation methods. In addition, the alkynyl Au (III) complex or the thin film formed by them can be used as a light-emitting layer for manufacturing a light-emitting device. Specifically, the alkynyl Au (III) complex exists in a light-emitting layer in the form of doping, so the maximum luminous intensity provided is different with doping concentration. The alkynyl Au (III) complex provided by the invention can still maintain high quantum efficiency at a large luminous intensity such as 1000 cd/m², and the efficiency roll-off is not obvious.

The alkynyl Au (III) complex provided by the invention presents thermally activated delayed fluorescence (TADF) at room temperature.

The alkynyl Au (III) complex provided by the invention mainly emits light with thermally activated delayed fluorescence (TADF) at room temperature; preferably, the TADF luminous efficiency shown at room temperature by the alkynyl Au (III) complex provided by the invention accounts for 25%-75% of the total fluorescence quantum efficiency.

The alkynyl Au (III) complex provided by the invention has a donor and acceptor groups that are sterically separated or distorted (that is, tridentate CANAC ligand substituted by dianion electricity-withdrawing), so that the energy difference between the singlet excited state and the triplet excited state is very small within the alkynyl Au (III) complex, which promotes the occurrence of reverse intersystem crossing, and presents TADF at room temperature, thereby obtaining high quantum efficiency. Such complex materials being used as emissive dopants in the preparation of OLEDs can greatly improve the luminescent properties (efficiency) of OLED devices. When luminance is 1000 cd/m², the external quantum efficiency EQE of the device still maintains a high level (>10%) at this luminance, but the efficiency attenuation is as low as 8%, which indicates that the compound can be used well as OLED materials.

In order to achieve the objective of the invention, the invention also provides a light-emitting device that uses the aforementioned alkynyl Au (III) complex as a light-emitting material or dopant.

In one example, the light-emitting device is an organic electroluminescent diode (OLED). In general, an OLED is composed of an anode and a cathode, between which it includes a hole injection layer, a hole transport layer, a light-emitting layer, an electron transport layer, and an electron injection layer.

In one example, the OLED uses a light-emitting layer having the aforementioned alkynyl Au (III) complex as a light-emitting material or doping material.

In one example, the OLED includes one or more light-emitting layers. When there are multiple light-emitting layers, the light-emitting materials or dopants contained in each light-emitting layer are the same or different, wherein at least one light-emitting layer contains light-emitting material or dopant having the aforementioned alkynyl Au (III) complex.

In one example, the light-emitting layer is prepared by any method selected from sublimation, vacuum deposition, spin coating, inkjet printing or other known preparation methods.

In one example, the doping concentration of the alkynyl Au (III) complex is 4-40% by mass percentage, including but not limited to 4%, 8%, 12%, 16%, 18%, 24%, 27%, 37%.

In one example, the OLED prepared by using the alkynyl Au (III) complex of Formular I shows maximum current efficiency more than 50 cd/A without light coupling out. In another example, the OLED prepared by using the alkynyl Au (III) complex of Formular I shows current efficiency more than 40 cd/A, or including but not limited to more than 40 cd/A, 50 cd/A, 60 cd/A, 70 cd/A.

In one example, the OLED prepared by using the alkynyl Au (III) complex of Formular I shows maximum power efficiency more than 50 lm/W without light coupling-out. In another example, the OLED prepared by using the alkynyl Au (III) complex of Formular I shows maximum power efficiency more than 40 lm/W, including but not limited to more than or equal to 40 lm/W, 50 lm/W, 60 lm/W, 70 lm/W.

In one example, the OLED prepared by using the alkynyl Au (III) complex of Formular I shows maximum external quantum efficiency more than 20% without light coupling-out. In another example, the OLED prepared by using the alkynyl Au (III) complex of Formular I shows maximum external quantum efficiency more than 17%, including but not limited to more than or equal to 17%, 18%, 19%, 20%, 21%. In another example, the maximum external quantum efficiency ranges from 15% to 25%.

In one example, the OLED prepared by using the alkynyl Au (III) complex of Formular I shows maximum external quantum efficiency more than 20% at 1000 cd/m² without light coupling-out. In another example, the OLED prepared by using the alkynyl Au (III) complex of Formular I shows external quantum efficiency more than 10%, including but not limited to more than or equal to 10%, 12%, 14%, 16%, 18%, 20%.

In one example, the device has efficiency roll-off less than 8% at 1000 cd/m². In another example, the device has efficiency roll-off less than 20%, or any percentage less than 20% at 1000 cd/m², including but not limited to less than 17%, 15%, 13%, 10%, 7%, 5% or 3%.

In one example, the device prepared by using the alkynyl Au (III) complex of Formular I shows CIE chromaticity coordinates of (0.38±0.08, 0.55±0.03).

The invention has the following beneficial effects:

The alkynyl Au (III) complex provided by the invention has excellent luminescent properties such as short luminescence life, high external quantum efficiency, and reduced efficiency roll. It is currently the best result obtained in the research of Au (III) complexes, especially alkynyl Au (III) complexes, and it is close or equivalent to the luminescent properties of the commercialized light-emitting martial having metal complexes such as Pt(II) and Ir(III) on the market, so it is expected to become a new type of light-emitting material for OLED.

In addition, the alkynyl Au (III) complex provided by the invention contains TADF or is mainly based on TADF luminescence. It is the first alkynyl Au (III) complex discovered with TADF at room temperature. Its radiation attenuation rate is the highest among all the alkynyl Au (III) complexes known to be used in light-emitting materials for OLED, which greatly overcomes the lack of the luminescent properties based on phosphorescence or ordinary fluorescence luminescence, and achieves high quantum efficiency.

### BRIEF DESCRIPTION OF THE DRAWINGS

FIG. 1 is a structural diagram of the light-emitting device of the invention.

FIG. 2 is an emission spectrum diagram of the Au (III) complex 101 provided by the invention in degassed toluene and at a concentration of 2×10⁻⁵ mol/L.

FIG. 3 is a UV absorption diagram of the Au (III) complex 101 provided by the invention in degassed toluene and at a concentration of 2×10⁻⁵ mol/L.

FIG. 4 is an emission spectrum diagram of the Au (III) complex 102 provided by the invention in degassed toluene and at a concentration of 2×10⁻⁵ mol/L.

FIG. 5 is a UV absorption diagram of the Au (III) complex 102 provided by the invention in degassed toluene and at a concentration of 2×10⁻⁵ mol/L.

FIG. 6 is an emission spectrum diagram of the Au (III) complex 103 provided by the invention in degassed toluene and at a concentration of 2×10⁻⁵ mol/L.

FIG. 7 is a UV absorption diagram of the Au (III) complex 103 provided by the invention in degassed toluene and at a concentration of 2×10⁻⁵ mol/L.

FIG. 8 is an emission spectrum diagram of the Au (III) complex 104 provided by the invention in degassed toluene and at a concentration of 2×10⁻⁵ mol/L.

FIG. 9 is a UV absorption diagram of the Au (III) complex 104 provided by the invention in degassed toluene and at a concentration of 2×10⁻⁵ mol/L.

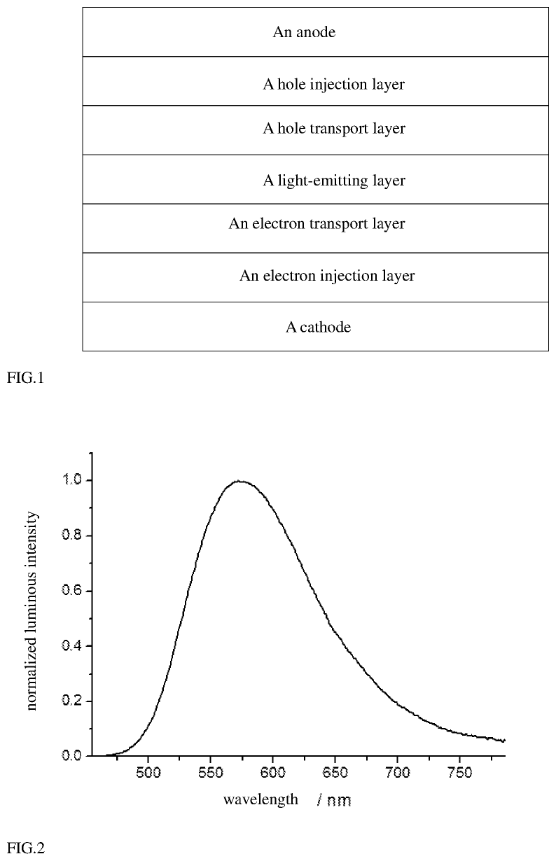

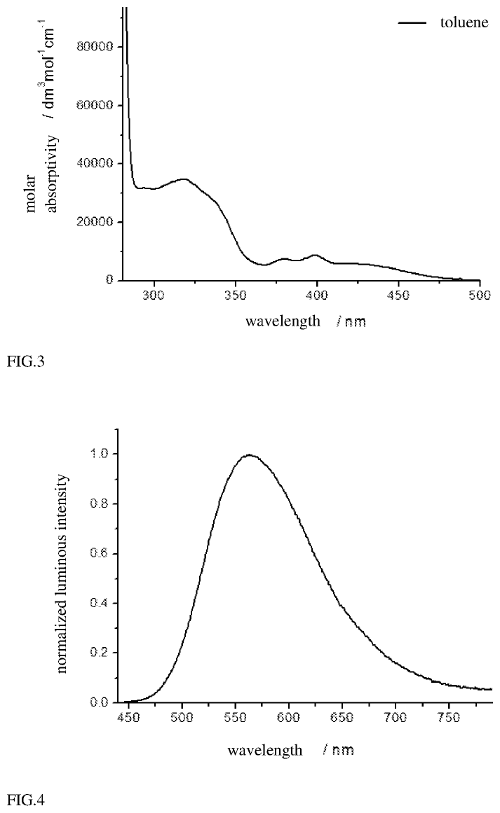

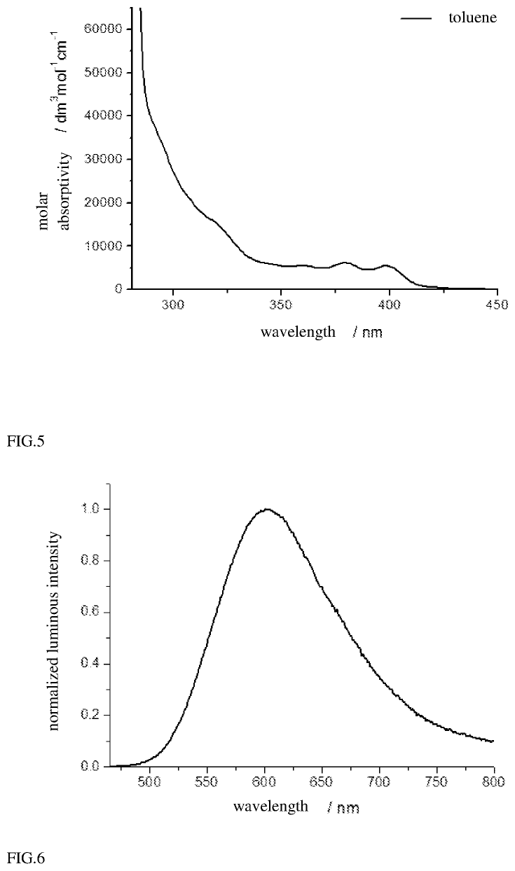

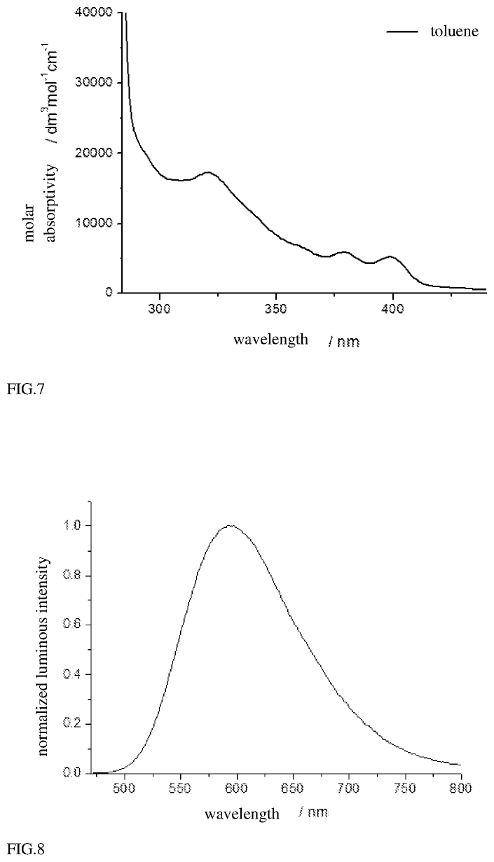

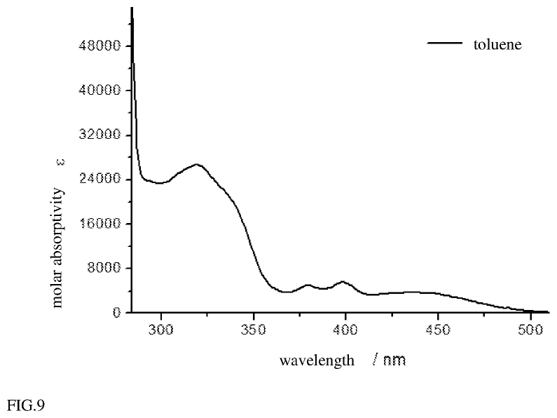

### DETAILED DESCRIPTION OF THE INVENTION

In order to make the invention clear and easy to understand, a Chinese comparison for the invention's examples involving English abbreviations is provided first, as follows:

TCTA: 4,4′,4″-tris(carbazol-9-yl) triphenylamine

TAPC: 4,4′-cyclohexylbis[N,N-bis(4-methylphenyl) aniline

TPBi: 1,3,5-tris(1-phenyl-1H-benzimidazol-2-yl)benzene

TmPyPb: 3,3′-[5′-[3-(3-pyridyl)phenyl][1,1′:3′,1″-terphenyl]-3,3″-diyl] two pyridine

HAT-CN: 2,3,6,7,10,11-hexacyano-1,4,5,8,9,12-hexaazatriphenylene

LiF: lithium fluoride

ITO: indium tin oxide

Al: aluminum

Examples are provided for describing the implementation of the invention as below. These examples should not be deemed as a limitation. Unless otherwise mentioned, percentage is all by weight, and proportion of solvent mixtures is all by volume.

### Example 1

In order to make the invention easy to understand, specific complexes 101-104 are taken as an example to introduce the preparation method of the alkynyl Au (III) complex of the invention in the following. The reaction formula is as follows:

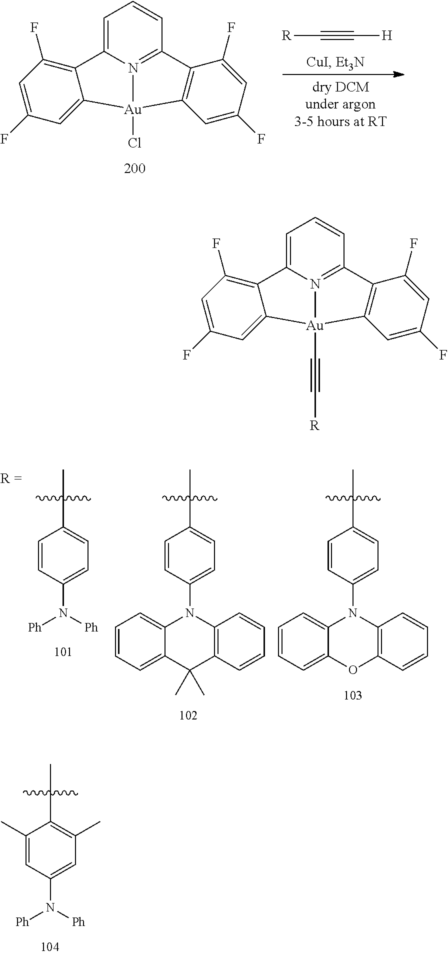

The complexes 101-104 were synthesized by referring to the methods reported in the existing literature. Except for different reagents, other reaction conditions were basically the same or similar. A person skilled in the art can change C\hat{ }N\hat{ }C—Au—Cl complexes and alkynyl reagents with different substrate structures under the same or similar conditions according to the reports in the existing literature to obtain different alkynyl Au (III) complex structures involved in the invention.

Among them, the structural characterization data of complexes 101-104 are as follows:

Complex 101

¹H NMR (500 MHz, CD₂Cl₂): δ 7.89 (t, J=8.5 Hz, 1H), 7.79 (d, J=8.0 Hz, 2H), 7.45 (d, J=6.0 Hz, 2H), 7.39 (d, J=8.5 Hz, 2H), 7.29 (t, J=7.5 Hz, 4H), 7.12 (d, J=7.5 Hz, 4H), 7.06 (t, J=7.5 Hz, 2H), 7.01 (d, J=8.5 Hz, 2H), 6.74-6.68 (m, 2H).

¹⁹F NMR (500 MHz, CD₂Cl₂): δ −104.19, −108.08

Complex 102

¹H NMR (500 MHz, CDCl₃): δ 7.95 (t, J=8.0 Hz, 1H), 7.86 (d, J=8.0 Hz, 2H), 7.82 (d, J=8.0 Hz, 2H), 7.63 (dd, J=6.5, 2.5 Hz, 2H), 7.47 (dd, J=8.0, 1.5 Hz, 2H), 7.33 (d, J=8.5 Hz, 2H), 7.01 (td, J=7.5, 1.5 Hz, 2H), 6.94 (td, J=8.0, 1.5 Hz, 2H), 6.72-6.67 (m, 2H), 6.37 (dd, J=8.0, 1.0 Hz, 2H), 1.70 (s, 6H).

¹⁹F NMR (500 MHz, CDCl₃): δ −102.72, −107.72

Complex 103

¹H NMR (500 MHz, CD₂Cl₂): δ 8.00 (t, J=8.0 Hz, 1H), 7.90 (d, J=8.0 Hz, 2H), 7.79 (d, J=8.0 Hz, 2H), 7.64 (d, J=6.0 Hz, 2H), 7.33 (d, J=8.5 Hz, 2H), 6.76 (t, J=10.5 Hz, 2H), 6.69-6.61 (m, 6H), 6.01 (d, J=7.0 Hz, 2H).

¹⁹F NMR (500 MHz, CD₂Cl₂): δ −103.88, −107.96

Complex 104

¹H NMR (500 MHz, CD₂Cl₂): δ 7.97 (t, J=8.0 Hz, 1H), 7.89 (d, J=8.5 Hz, 2H), 7.68 (dd, J=6.5, 2.0 Hz, 2H), 7.27 (t, J=7.5 Hz, 4H), 7.09 (d, J=8.0 Hz, 4H), 7.03 (t, J=7.5 Hz, 2H), 6.81 (s, 2H), 6.75-6.70 (m, 2H), 2.49 (s, 6H).

¹⁹F NMR (500 MHz, CD₂Cl₂): δ −104.18, −108.11

### Example 2

The photophysical properties of Complexes 101-104 were tested at room temperature, and the results are shown in Table 1 below:

TABLE 1
Photophysical data of alkynyl Au (III) complexes measured in
different environments at room temperature

| | | | luminescence | |
|---|---|---|---|---|
| | absorption | | In toluene | In PMMA film |
| | λ_{abs} [nm] | | λₑₘ [nm] | λₑₘ [nm] |
| | (ε [×10³ mol⁻¹ | | (Φ; τ [μs]; | (Φ; τ [μs]; |
| Complex | dm³ cm⁻¹]) | | kᵣ [10⁵ s⁻¹]) | kᵣ [10⁵ s⁻¹]) |
| 101 | 294 | (31.78), | 574 | 577 |
| | 318 | (34.69), | (0.60; 0.78; 7.69) | (0.88; 0.85; 10.35) |
| | 379 | (7.39), | | |
| | 398 | (8.66), | | |
| | 426 | (br, 5.68) | | |
| 102 | 320 | (15.24), | 562 | 560 |
| | 359 | (5.12), | (0.49; 0.80; 6.13) | (0.67; 1.43; 4.69) |
| | 379 | (6.17), | | |
| | 398 | (5.53), | | |
| | 412 | (br, 1.15) | | |
| 103 | 290 | (20.45), | 603 | 602 |
| | 321 | (17.27), | (0.57; 0.84; 6.79) | (0.51; 0.98; 5.20) |
| | 360 | (6.77), | | |
| | 379 | (5.90), | | |
| | 399 | (5.28), | | |
| | 417 | (br, 1.04) | | |
| 104 | 319 | (26.74), | 594 | 572 |
| | 338 | (20.49), | (0.25; 0.33; 7.58) | (0.63; 0.90; 7.00) |
| | 380 | (4.99), | | |
| | 398 | (5.59), | | |
| | 435 | (br, 3.78) | | |

λ_{abs}: wavelength of absorbed light,
ε: molar extinction coefficient,
λₑₘ: wavelength of emitted light,
Φ: external quantum efficiency,
τ: luminescence lifetime,
kᵣ: radiation attenuation rate

Analysis: It can be seen from the above Table 1

1) The metal complexes 101-104 have a strong absorption peak at the absorption wavelength range of 294-338 nm, where the extinction coefficient ε is between (15-35)×10³ mol^{-l}dm³ cm⁻¹, and have a moderately strong absorption peak at the wavelength range of 359-399 nm, which is the characteristic absorption peak of CANAC ligand, where the extinction coefficient ε is between (5-9)×10³ mol^{-l}dm³ cm⁻¹. Behind the characteristic absorption peak of the ligand, there is a weak and wide absorption peak, which is between 412-435 nm (ε=(1-6)×10³ mol⁻¹dm³ cm⁻¹).

2) Whether the above-mentioned complex is dissolved in toluene or doped in polymethyl methacrylate PMMA film, strong fluorescence emission can be measured, and the measured emission wavelength is basically in the yellow wavelength band. The photoluminescence quantum efficiency is mainly between 50-90%, up to 88%, the luminescence lifetime is less than 2 μs, and the radiation decay rate kr is between 4.69-10.35×10⁵

By repeatedly exploring for experimental conditions, light-emitting devices with different structures and composition parameters have been designed and prepared according to the Complexes 101-104, respectively, as follows.

### Example 3—OLED1

First, the Complex 101 is used as a dopant to set different doping concentrations that are applied to the light-emitting layer of the light-emitting device, and the structure of OLED 1 is obtained through design. The structure from the anode to the cathode is as follows:

ITO/HAT-CN(5 nm)/TAPC(50 nm)/TCTA: Complex 101 (10 nm)/TmPyPb (40 nm)/LiF (1.2 nm)/Al (100 nm)

Then, according to the preset structure and composition parameters, the light-emitting device is roughly prepared, as following preparation process:

a) a transparent glass substrate coated with ITO being put to use, ultrasonically being cleaned with detergent and rinsed with deionized water, and dried for later use;

b) transferring the dried substrate to a vacuum chamber, sequentially obtaining functional layers of preset thickness through sequential thermal evaporation deposition: a hole injection layer HAT-CN with a thickness of 5 nm, and a hole transport layer with a thickness of 50 nm;

c) using the Complex 101 as a dopant to be dissolved in TCTA according to different concentration ratios, and forming a thin film by spin coating on the basis of the deposited hole transport layer to obtain a light-emitting layer by solution method;

d) Then, depositing a TmPyPb electron transport layer with a thickness of 40 nm, a LiF buffer layer with a thickness of 1.2 nm and an Al cathode with a thickness of 100 nm on the organic film by evaporation deposition in sequence.

Finally, the prepared light-emitting device (OLED1) is measured for performance:

The measurement conditions are that: EL spectrum, luminance, current efficiency, power efficiency and CIE coordination are measured by C9920-12 Hamamatsu photonics absolute external quantum efficiency measurement system, and the voltage-current characteristics are measured by using Keithley 2400 source measurement unit. All devices are characterized at room temperature in the atmosphere without encapsulation.

The measured luminescent properties include: maximum luminance L, current efficiency CE, power efficiency PE, external quantum efficiency EQE, and international color standard CIE. The results are shown in Table 2 below:

TABLE 2
Luminescent properties parameters of the light-emitting
device (OLED 1) made with Complex 101

| | | CE | | PE | | | | |
|---|---|---|---|---|---|---|---|---|
| doping | | [cd A⁻¹] | | [lm W⁻¹] | | EQE [%] | | |
| concentration | | | 1000 | | 1000 | | 1000 | |
| (wt %) | L[cd m⁻²] | Max | cd m⁻² | Max | cd m⁻² | Max | cd m⁻² | CIE[(x, y)] |
| 4 | 7870 | 68.94 | 52.95 | 66.46 | 43.01 | 22.56 | 17.32 | (0.33, 0.55) |
| 8 | 12000 | 63.18 | 53.74 | 60.46 | 42.55 | 20.48 | 17.49 | (0.35, 0.55) |
| 12 | 14500 | 56.47 | 51.82 | 51.50 | 39.65 | 18.27 | 16.79 | (0.34, 0.56) |

### Example 4—OLED2

First, the Complex 102 is used as a dopant to set different doping concentrations that are applied to the light-emitting layer of the light-emitting device, and the structure of OLED 2 is obtained through design. The structure from the anode to the cathode is as follows:

ITO/HAT-CN(5 nm)/TAPC (40 nm)/TCTA(10 nm)/TCTA:TPBi:Complex102 (10 nm)/TPBi(10 nm)/TmPyPb (40 nm)/LiF (1.2 nm)/Al (100 nm)

Then, according to the preset structure and composition parameters of OLED 2, and the sequence of composition from anode to cathode, a light-emitting device is prepared. The preparation process is basically the same as the preparation process of OLED 1 in Example 3, only has difference with changing specific composition and corresponding parameters.

Finally, the performance of the light-emitting device (OLED 2) is measured according to the same conditions and methods as in Example 3. The results are shown in Table 3 as follows:

TABLE 3
Luminescent properties parameters of the light-emitting
device (OLED 2) made with Complex 102

| | | CE | | PE | | | | |
|---|---|---|---|---|---|---|---|---|
| doping | | [cd A⁻¹] | | [lm W⁻¹] | | EQE [%] | | |
| concentration | | | 1000 | | 1000 | | 1000 | |
| (wt %) | L[cd m⁻²] | Max | cd m⁻² | Max | cd m⁻² | Max | cd m⁻² | CIE[(x, y)] |
| 4 | 7500 | 32.38 | 17.95 | 40.11 | 13.60 | 10.47 | 5.79 | 0.35, 0.56 |
| 8 | 9140 | 42.34 | 23.82 | 52.00 | 18.66 | 13.46 | 7.65 | 0.36, 0.56 |
| 12 | 9260 | 47.81 | 28.08 | 57.77 | 22.07 | 15.07 | 9.04 | 0.37, 0.56 |
| 18 | 10700 | 50.28 | 30.44 | 60.76 | 26.57 | 16.20 | 9.72 | 0.38, 0.56 |
| 27 | 11050 | 53.44 | 31.85 | 64.58 | 26.95 | 17.34 | 10.11 | 0.39, 0.56 |
| 37 | 11400 | 52.55 | 33.48 | 63.49 | 29.21 | 17.02 | 10.71 | 0.40, 0.56 |

### Example 5—OLED3

First, the Complex 103 is used as a dopant to set different doping concentrations that are applied to the light-emitting layer of the light-emitting device, and the structure of OLED 3 is obtained through design. The structure from the anode to the cathode is as follows:

ITO/HAT-CN(5 nm)/TAPC (50 nm)/TCTA: Complex 103 (10 nm)/TmPyPb (50 nm)/LiF (1.2 nm)/Al (100 nm)

Then, according to the preset structure and composition parameters of OLED 3, and the sequence of composition from anode to cathode, a light-emitting device is prepared. The preparation process is basically the same as the preparation process of OLED 1 in Example 3, only has difference with changing specific composition and corresponding parameters.

Finally, the performance of the light-emitting device (OLED 3) is measured according to the same conditions and methods as in Example 3. The results are shown in Table 4 as follows:

TABLE 4
Luminescent properties parameters of the light-emitting
device (OLED 3) made with Complex 103

| | | CE | | PE | | | | |
|---|---|---|---|---|---|---|---|---|
| doping | | [cd A⁻¹] | | [lm W⁻¹] | | EQE [%] | | |
| concentration | | | 1000 | | 1000 | | 1000 | |
| (wt %) | L[cd m⁻²] | Max | cd m⁻² | Max | cd m⁻² | Max | cd m⁻² | CIE[(x, y)] |
| 8 | 16500 | 66.61 | 55.82 | 68.43 | 46.32 | 22.15 | 18.24 | 0.38, 0.55 |
| 16 | 24800 | 61.26 | 56.20 | 61.33 | 46.46 | 21.44 | 19.34 | 0.41, 0.54 |
| 24 | 25200 | 48.20 | 45.17 | 46.19 | 36.26 | 18.33 | 16.36 | 0.45, 0.52 |

### Example 6—OLED4

First, the Complex 104 is used as a dopant to set different doping concentrations that are applied to the light-emitting layer of the light-emitting device, and the structure of OLED 4 is obtained through design. The structure from the anode to the cathode is as follows:

ITO/HAT-CN(5 nm)/TAPC (40 nm)/TCTA(10 nm)/TCTA: TPBi: Complex 104 (10 nm)/TPBi (10 nm)/TmPyPb (40 nm)/LiF (1.2 nm)/Al (100 nm)

Then, according to the preset structure and composition parameters of OLED 4, and the sequence of composition from anode to cathode, a light-emitting device is prepared. The preparation process is basically the same as the preparation process of OLED 1 in Example 3, only has difference with changing specific composition and corresponding parameters.

Finally, the performance of the light-emitting device (OLED 3) is measured according to the same conditions and methods as in Example 3. The results are shown in Table 5 as follows:

TABLE 5
Luminescent properties parameters of the light-emitting
device (OLED 4) made with Complex 104

| | | CE | | PE | | | | |
|---|---|---|---|---|---|---|---|---|
| doping | | [cd A⁻¹] | | [lm W⁻¹] | | EQE [%] | | |
| concentration | | | 1000 | | 1000 | | 1000 | |
| (wt %) | L[cd m⁻²] | Max | cd m⁻² | Max | cd m⁻² | Max | cd m⁻² | CIE[(x, y)] |
| 4 | 71000 | 70.57 | 65.91 | 73.91 | 56.12 | 23.37 | 21.80 | 0.40, 0.55 |

From Examples 3-6, it can be seen that the OLEDs prepared by using Complexes 101-104 all show excellent luminescent properties. For example, light-emitting devices generally can obtain external quantum efficiency more than 20%, and even at 1000 cd/m², can still maintain the external quantum efficiency more than 20% or close to 20%. It has changed the existing circumstances that gold complexes are very poor at 1000 cd/m², and so far no related results have been reported in the literature.

Comparing the results measured in Examples 3-6 with the results reported in the existing literature(J. Am. Chem. Soc. 2014, 136, 17861-17868; Angew. Chem. Int. Ed. 2018, 57, 5463-5466; J. Am. Chem. Soc. 2017, 139, 10539-10550; J. Am. Chem. Soc. 2010, 132, 14273-14278), it can be seen that the external quantum efficiency of the Complexes 101-104 can be obtained with 17.3-23.4%, which is much higher than the highest result (13.5%) in the literature, and the complexes have a lower efficiency roll-off and a shorter luminescence lifetime.

Comparison result of the luminescence parameters between the complexes provided by the invention and the prior art is summarized as follows.

| | | | radiation | | efficiency |
|---|---|---|---|---|---|
| | | luminescence | attenuation | | roll-off at |
| | PLQY | lifetime | rate | EQE | 1000 cd/m² |
| prior art | 20-84% | 10 us-1 ms | 10²-10³s⁻¹ | −13.5% | 1-90% |
| this | 51-88% | 500 ns-2 μs | 10⁵-10⁶s⁻¹ | 17.3-23.4% | 8% |
| invention | | | | | |

It is worth mentioning that, after testing, the efficiency roll-off of the light-emitting devices made of all the above complexes is reduced to 20% in the range of 1000 cd/m², and is not obvious, which is very conducive to its commercial application.

### Example 7

The luminescent properties of the alkynyl Au (III) complex provided by the invention is much better than that reported in the existing literature, and its radiation attenuation rate is 4.69-10.35×10⁵ s⁻¹, indicating that the luminescence of these complexes in this example may not be based on the principle of phosphorescence. In addition, when measuring the luminescence lifetime of the complexes in the above examples at different temperatures, it appears that the luminescence lifetime increases sharply with the decrease in temperature. According to the current understanding of a person skilled in the art, this phenomenon preliminarily reveals that the light-emitting mechanism is likely to change after the temperature descends from room temperature. The phenomenon that the light-emitting mechanism at low temperature reduces the radiation decay rate is consistent with the characteristics of typical light-emitting materials with TADF.

Furthermore, the known parameters and luminescent properties data of the complex in this example are substituted into the existing theoretical Equation (1) to verify whether the complex is consistent with the typical complex with TADF. The Equation (1) is a equation where the luminescence lifetime is related to temperature and that is used to explain Thermally Activated Delayed Fluorescence. After calculation, R²=0.972, indicates that the light-emitting mechanisms of the both are extremely consistent. The energy differences calculated out between the singlet excited state and the triplet excited state of the complex 101-104 are 632, 176, 207, and 295 cm⁻¹, respectively, so the energy gap is much lower than that of conventional fluorescence or phosphorescence, which indicates the strong photoluminescence observed at room temperature is mainly fluorescence based on the principle of TADF.

$$τ ( T ) = \frac{3 + exp [ - \frac{Δ E ( {S}_{1} - {T}_{1} )}{{k}_{B} T} ]}{\frac{3}{τ ( {T}_{1} )} + \frac{1}{τ ( {S}_{1} )} exp [ \frac{Δ E ( {S}_{1} - {T}_{1} )}{{k}_{B} T} ]} \qquad ( 1 )$$

The structural characteristics of the alkynyl Au (III) complexes provided by the examples of the invention are a pair of ligands sterically separated, including a donor (amino-substituted arylacetylene ligand-C≡C-TPA) and an acceptor (dianion fluorine-substituted tridentate CANAC ligand). In order to more deeply understand the light-emitting principle of the complex in mechanism, in this example theoretical calculation is made by analyzing and establishing a model to take complex 101 as an example and apply density functional theory, with known that the donor and acceptor in the complex provide the singlet HOMO orbital and triplet LUMO orbital for electron transition, respectively, and the spatial separation of the ligands forms a different dihedral angle d between the CANAC ligand and the benzene ring connected to the alkyne on the —C≡C-TPA ligand, so that the HOMO and LUMO orbitals are separated. The different dihedral angle d reduces the energy gap between the S1 and T1 state orbitals to varying degrees, which is easy to generate ligand-to-ligand charge transfer (LLCT), and the energy difference between different dihedral angles is so small that the free rotation of the benzene ring connected to the alkyne can occur at room temperature.

Table 6 as follows shows the adiation attenuation rate constants of S1 and T1 calculated out. The adiation attenuation rate constants of phosphorescence in the T1 state is that when d=5.4°, kr=4.04×10² s⁻¹, when d=101°, kr=2.14×10³ s⁻¹. That is far from the adiation attenuation rate constant of 10⁵-10⁶ s⁻¹ that we obtained in Example 2 and cannot be thoroughly explained. Therefore, we cannot attribute the light experimentally observed only to phosphorescence. Regarding the TADF mechanism, kr changes to 6.47×10² s⁻¹ at d=5.4° and 1.22×10⁶ s⁻¹ at d=101°, and considering that the kr value experimentally measured is the sum of the kr value for all radiable transitions channel, so having TADF is the most likely mechanism.

It can be inferred from this that the new type of the alkynyl Au (III) complex provided by us contains TADF-based luminescence, and even TADF luminescence predominates, so that the alkynyl Au (III) complex provided by the invention has higher adiation attenuation rate, lower luminescence lifetime and lower efficiency roll-off.

There are reports in the existing literature (J. Am. Chem. Soc. 2014, 136, 17861-17868; Angew. Chem. Int. Ed. 2018, 57, 5463-5466) that the MCP film made of the alkynyl Au (III) complex shows that the light quantum efficiency of phosphorescence can reach 83%. This type of compound emits light in the solid film based on the excimers generated from π-π stacking of C\hat{ }N\hat{ }C ligands. Compared with the reports in the existing literature that the alkynyl Au (III) complex emits light based on the principle of phosphorescence, the light-emitting principle on which the alkynyl Au (III) complex provided by the invention is based is different. Therefore, the luminescent properties of the alkynyl Au (III) complex provided by the invention is much better than the reported alkynyl Au (III) complex, and compared with all known Au (III) complexes, the invention has such a best result that it is novelty and has important significance and progress.

In summary, according to the examples of the invention, the alkynyl Au (III) complex provided by the invention has the following advantages:

1. By introducing an amino-substituted arylacetylene ligand —C≡C-TPA on the trivalent central Cu (III), and a dianion tridentate C\hat{ }N\hat{ }C ligand substituted by 2 or more electron withdrawing groups to obtain excellent luminescent properties, its photoluminescence quantum efficiency is up to 88%, and has a adiation attenuation rate constant (10⁵-10⁶ s⁻¹) and short luminescence lifetime (<2 μs), and compared with most Au (III) complexes having the luminescence lifetime of 50 μs-500 μs in the prior art, its luminescence lifetime is shortened by about 10-100 times, which is conductive to obtain higher quantum efficiency and serve as light-emitting material used for manufacturing OLED devices in a wider doping concentration range.

2. The OLED device prepared by using the alkynyl Au (III) complex provided by the invention has excellent luminescent properties, and the measured external quantum efficiency (EQE) is up to 23.37%, generally more than 20% or close to 20%, even more than 50% of the result obtained from the alkynyl Au (III) complex that is equivalent to the external quantum efficiency of the commercially available light-emitting materials having complexes such as Pt(II) and Ir(III) complexes. When the luminance reaches the practical requirement of 1000 cd/m², the efficiency roll-off decreases to 8%, and the EQE is still as high as 21.8%. Even when the luminance is 10000 cd/m², the efficiency roll-off is not obvious, so this type of Au (III) complex has superior performance as a new OLED light-emitting material.

3. By studying the luminescent properties and light-emitting mechanism of the alkynyl Au (III) complex and combining it with the existing theoretical calculation results, after analysis it shows that it is different from the reports on the alkynyl Au (III) complex based on the principle of phosphorescence in the prior art. The invention provides the luminescence of alkynyl Au (III) complexes having TADF or mainly based on the principle of TADF. The adiation attenuation rate is estimated to be 4.7-10.4×10⁵ s⁻¹, which is the highest among all alkynyl Au (III) compounds. This compound is the first alkynyl Au (III) complex with TADF discovered at room temperature. Due to the spin-forbidden transition of phosphorescence, TADF is a more efficient way to attenuate radiation than phosphorescence, and greatly overcomes the shortage in luminescent properties brought by phosphorescence or ordinary fluorescent luminescence, which is conducive to obtaining high EQE at room temperature.

4. In addition, the metal used in the alkynyl Au (III) complex provided by the invention is cheaper than Pt(II), Ir(III), and Ru(II), which is beneficial to reduce the cost of light-emitting materials. In light-emitting devices, especially in the commercial development of OLED, it has a great application prospect.

5. Compared with the Au (III) complex in the prior art, the structure is simpler and easy to prepare. In addition, it is difficult for the light-emitting device prepared by the solution method to achieve the same or substantially the same light-emitting performance as the vacuum deposition method, while the alkynyl Au (III) complex provided by the invention can be applied to the preparation of OLED devices by the solution method, and its performance is basically the same with the performance of the light-emitting devices prepared by the vacuum deposition method, which is beneficial to simplify the production process of the OLED device and save cost.

1.-11. (canceled)

12. An alkynyl Au (III) complex having a chemical structure of Formula I, 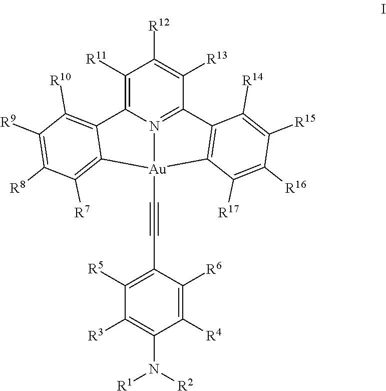
where, R¹ and R² are independently a hydrogen atom, a deuterium atom, a substituted or unsubstituted alkyl group, a substituted or unsubstituted cycloalkyl group, a substituted or unsubstituted heterocycloalkyl group, a substituted or unsubstituted aryl group, a substituted or unsubstituted heteroaryl group, and R¹ and R² can also form a nitrogen-having heterocyclic 5-membered ring or a nitrogen-having heterocyclic 6-membered ring with a N atom connected to them,
R³-R⁶, R⁷-R¹⁰ and R¹⁴-R¹⁷ are independently a hydrogen atom, a deuterium atom, a halogen atom, a trifluoromethyl group, a nitro group, a nitroso group, a cyano group, an isocyano group, a carboxyl group, a sulfonic acid group, a hydroxyl group, a sulfhydryl group, a substituted or unsubstituted alkoxy group, a substituted or unsubstituted aryloxy group, a substituted or unsubstituted alkylsulfonyl group, a substituted or unsubstituted arylsulfonyl group, a substituted or unsubstituted amino group, a substituted or unsubstituted alkyl group, a substituted or unsubstituted cycloalkyl group, a substituted or unsubstituted heterocycloalkyl group, a substituted or unsubstituted aryl group, a substituted or unsubstituted heteroaryl group, and two adjacent groups in R⁷-R¹⁰ and R¹⁴-R¹⁷ can also partially or completely form a 5-8 membered ring with 2 or 4 carbon atoms in the connected parent ring;
at least two groups in R⁷-R¹⁷ are electron-withdrawing substituents, and said electron-withdrawing substituents are independently a F atom, a Cl atom, a trifluoromethyl group, a nitro group, a nitroso group, a cyano group, an isocyano group, a carboxyl group or a sulfonic acid group, or are an aryl group, an heteroaryl group, a 1-unsaturated alkyl group, a 1-oxoalkyl group, an alkylsulfonyl group or an arylsulfonyl group that are substituted by at least one of F, Cl, a trifluoromethyl group, a nitro group, a nitroso group, a cyano group, an isocyano group, a carboxyl group or a sulfonic acid group,
wherein R¹¹-R¹³ are independently a hydrogen atom, a deuterium atom, a halogen atom, a trifluoromethyl group, a nitro group, a nitroso group, a cyano group, an isocyano group, a carboxyl group, a sulfonic acid group, a hydroxyl group, a sulfhydryl group, a substituted or unsubstituted alkoxy group having 1-10 carbon atoms, a substituted or unsubstituted aryloxy group having 6-12 carbon atoms, a substituted or unsubstituted alkylsulfonyl group having 1-10 carbon atoms, a substituted or unsubstituted arylsulfonyl group having 6-12 carbon atoms, a substituted or unsubstituted amino group having 0-12 carbon atoms, a substituted or unsubstituted alkyl group having 1-10 carbon atoms, a substituted or unsubstituted cycloalkyl group having 5-12 carbon atoms, a substituted or unsubstituted heterocycloalkyl group having 3-12 carbon atoms, or a substituted or unsubstituted heteroaryl group having 3-12 carbon atoms.

13. The alkynyl Au (III) complex according to claim 12, wherein R¹ and R² are independently a hydrogen atom, a deuterium atom, a substituted or unsubstituted alkyl group having 1-20 carbon atoms, a substituted or unsubstituted cycloalkyl group having 4-20 carbon atoms, a substituted or unsubstituted heterocycloalkyl group having 4-20 carbon atoms, a substituted or unsubstituted aryl group having 6-20 carbon atoms, or a substituted or unsubstituted heteroaryl group having 4-20 carbon atoms, and R¹ and R² can also form a nitrogen-having heterocyclic 5-membered ring or a nitrogen-having heterocyclic 6-membered ring with a N atom connected to them,
preferably, R¹ and R² are respectively a substituted or unsubstituted aryl group having 6-20 carbon atoms, or R¹ and R² can also form a nitrogen-having heterocyclic 5-membered ring or a nitrogen-having heterocyclic 6-membered ring with a N atom connected to them, which refers to that the direct bonding between the aromatic rings of R¹ and R² forms a 6-5-6 fused ring structure with a N atom connected to them or that the bonding of the substituents on that aromatic ring forms a 6-6-6 fused ring structure with a N atom connected to them.

14. The alkynyl Au (III) complex according to claim 12, wherein R³-R⁶ and R⁷-R¹⁷ are independently a hydrogen atom, a deuterium atom, a halogen atom, a trifluoromethyl group, a nitro group, a nitroso group, a cyano group, an isocyano group, a carboxyl group, a sulfonic acid group, a hydroxyl group, a sulfhydryl group, a substituted or unsubstituted alkoxy group having 1-20 carbon atoms, a substituted or unsubstituted aryloxy group having 6-20 carbon atoms, a substituted or unsubstituted alkylsulfonyl group having 1-20 carbon atoms, a substituted or unsubstituted arylsulfonyl group having 6-20 carbon atoms, a substituted or unsubstituted amino group having 0-20 carbon atoms, a substituted or unsubstituted alkyl group having 1-20 carbon atoms, a substituted or unsubstituted cycloalkyl group having 5-20 carbon atoms, a substituted or unsubstituted heterocycloalkyl group having 3-20 carbon atoms, a substituted or unsubstituted aryl group having 6-20 carbon atoms, or a substituted or unsubstituted heteroaryl group having 3-20 carbon atoms.

15. The alkynyl Au (III) complex according to claim 12, wherein optionally at least two groups in R⁷-R¹⁰ and R¹⁴-R¹⁷ are independently a F atom, a Cl atom, a trifluoromethyl group, a nitro group, a nitroso group, a cyano group, an isocyano group, a carboxyl group, a sulfonic acid group, a substituted or unsubstituted aryl group having 6-12 carbon atoms, a substituted or unsubstituted heteroaryl group having 4-12 carbon atoms, a substituted or unsubstituted 1-unsaturated alkyl group having 2-10 carbon atoms, a substituted or unsubstituted 1-oxoalkyl group having 1-10 carbon atoms, a substituted or unsubstituted alkylsulfonyl group having 1-10 carbon atoms, or a substituted or unsubstituted arylsulfonyl group having 6-12 carbon atoms, where among said substituted or unsubstituted aryl group having 6-12 carbon atoms, said substituted or unsubstituted 1-unsaturated alkyl group having 2-10 carbon atoms, said substituted or unsubstituted 1-oxoalkyl group having 1-10 carbon atoms, said substituted or unsubstituted alkylsulfonyl group having 1-10 carbon atoms sand said substituted or unsubstituted arylsulfonyl group having 6-12 carbon atoms, the substitution refers to being substituted by at least one of a F atom, a Cl atom, a trifluoromethyl group, a nitro group, a nitroso group, a cyano group, an isocyano group, a carboxyl group and a sulfonic acid group.

16. The alkynyl Au (III) complex according to claim 12, wherein R³-R⁶ are independently a hydrogen atom, a deuterium atom, a Br atom, a I atom, a trimethylsilyl atom, a hydroxyl atom, a sulfhydryl atom, a substituted or unsubstituted alkoxy group having 1-10 carbon atoms, a substituted or unsubstituted aryloxy group having 6-12 carbon atoms, a substituted or unsubstituted amino group having 0-10 carbon atoms, a substituted or unsubstituted alkyl group having 1-10 carbon atoms, a substituted or unsubstituted cycloalkyl group having 5-12 carbon atoms, a substituted or unsubstituted heterocycloalkyl group having 3-12 carbon atoms, a substituted or unsubstituted aryl group having 6-12 carbon atoms, or a substituted or unsubstituted heteroaryl group having 3-12 carbon atoms.

17. The alkynyl Au (III) complex according to claim 12 having one of the following chemical structural formulas:

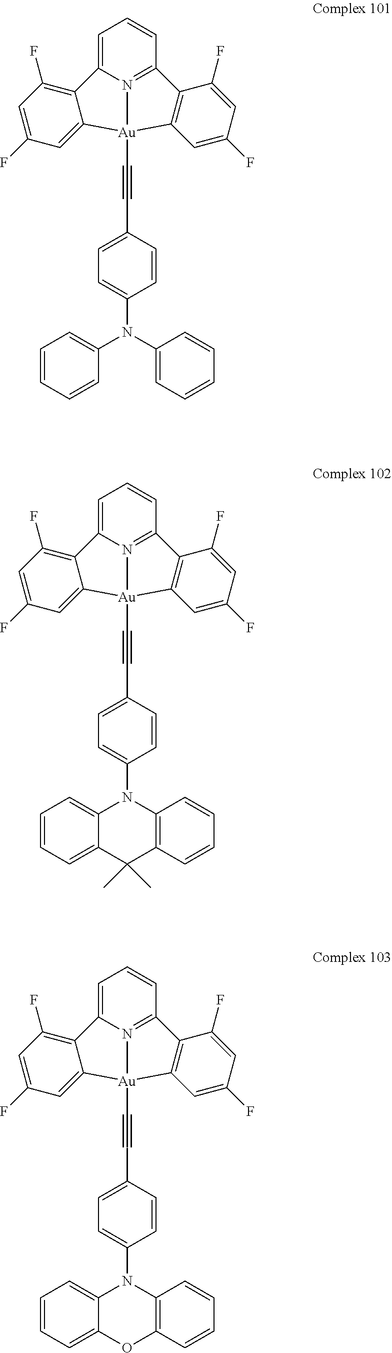

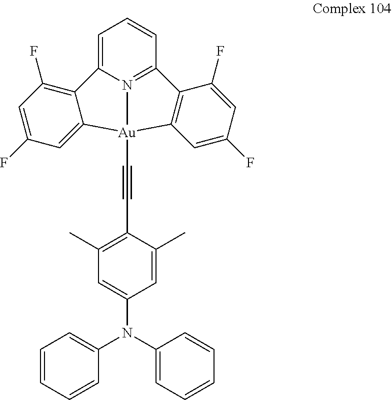

18. A light-emitting device that uses the alkynyl Au (III) complex according to any one of claims 1-6 as a light-emitting material or dopant.

19. The light-emitting device according to claim 18, wherein said light-emitting device includes an anode and a cathode, and a hole injection layer, a hole transport layer, a light-emitting layer, an electron transport layer, and an electron injection layer are included in turn between said anode and said cathode, said alkynyl Au (III) complex is located in said light-emitting layer.

20. The light-emitting device according to claim 18, wherein there are one or more light-emitting layers, when there are multiple light-emitting layers, the light-emitting materials or dopants contained in each light-emitting layer are the same or different, wherein at least one light-emitting layer contains said alkynyl Au (III) complex, and/or,
the light-emitting layer film of said light-emitting device is manufactured by vacuum deposition or solution method, and/or,
the doping concentration of the alkyne fund (III) complex is 4-40% by mass percentage.

21. The light-emitting device according to any one of claim 18, wherein without light coupling-out, said light-emitting device has maximum current efficiency more than 50 cd/A and/or maximum power efficiency more than 50 lm/W and/or maximum external quantum efficiency more than 17%, and/or, has maximum external quantum efficiency more than 10% at 1000 cd/m², and/or efficiency roll-off less than 20% at 1000 cd/m².
